(19) United States
(12) Patent Application Publication
(10) Pub. No.: US 2010/0309721 A1
(43) Pub. Date: Dec. 9, 2010

(54) NONVOLATILE SEMICONDUCTOR MEMORY DEVICE

(76) Inventor: Osamu NAGAO, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/793,018

(22) Filed: Jun. 3, 2010

(30) Foreign Application Priority Data
Jun. 5, 2009 (JP) 2009-136338

(51) Int. Cl. G11C 16/04

(52) U.S. Cl. 365/185.03; 365/189.05

(57) ABSTRACT

According to one embodiment, a nonvolatile semiconductor memory device includes a memory cells, a bit line, a sense amplifier, a memory circuit and an arithmetic circuit. The memory cells store multiple values in one memory cell. The bit line connected with the memory cells. The sense amplifier supplies a write voltage to the bit line. The memory circuit stores one of write data that is to be written in the memory cell and the number of writes. The arithmetic circuit changes the write data stored in the memory circuit to the number of writes and updates the number of writes. The arithmetic circuit controls the write voltage supplied from the sense amplifier based on the write data, and sets the number of writes in accordance with the write data stored in the memory circuit upon confirmation that each memory cell has reached a predetermined threshold voltage.

### CROSS-REFERENCE TO RELATED APPLICATIONS

This application is based upon and claims the benefit of priority from Japanese Patent Application No. 2009-136338, filed Jun. 5, 2009; the entire contents of which are incorporated herein by reference.

### FIELD

Embodiments described herein relate generally to an electrically programmable nonvolatile semiconductor memory device, and relates to, e.g., a NAND flash memory.

### BACKGROUND

In a NAND flash memory, a structure in which a plurality of memory cells are connected in series is determined as a basic unit (NAND unit), and one end of this NAND unit is connected to a bit line via a select gate (SGD) whilst the other end is connected with a source line via a select gate (SGS).

Reading and writing in the NAND flash memory are collectively performed in units called one page that achieves connection with one word line. Further, a page aggregate sandwiched between the select gate (SGD) on the bit line side and the select gate (SGS) on the source line side constitutes a block.

To cancel out a Yupin effect in the bit line and word line directions, there is a method of dividing a write method into “rough writing” and “actual writing” to be performed. Furthermore, there is a method of performing N writes after a given threshold voltage is exceeded and then terminating writing when a read operation in rough writing is not required. N is a value which differs depending on a threshold voltage of each value in a multilevel product in which memory cells store multiple values. This method has the merit that verification at a threshold voltage of each value is not required and hence the time per write loop is shortened, which leads to a reduction in write time. It should be noted that the Yupin effect means that, if the gap between memory cells adjacent to each other is narrow, the influence of parasitic capacitance between adjacent elements increases to deviate a threshold value.

In this method, if one of the latches that save data during writing is not required, an operation of, e.g., inputting next write data to this latch (a cache operation), may be performed (see, e.g., JP-A 2006-134558 [KOKAI]).

However, in the method of performing N writes after a given threshold voltage is exceeded and then terminating writing, and in the cache operation, a data transfer operation must be performed many times to set or change write data that is to be latched or to set or change the number of writes, which obstructs a reduction in write time.

### BRIEF DESCRIPTION OF THE DRAWINGS

FIG. 1 is a block diagram showing a configuration of a NAND flash memory according to a first embodiment;

FIG. 2 is a block diagram showing a configuration of a bit line control circuit in the NAND flash memory according to the first embodiment;

FIG. 3 is a view showing a distribution of threshold voltages of four values in the memory cell;

FIG. 4 is a flowchart showing a write operation in the NAND flash memory according to the first embodiment;

FIG. 5 is a view showing latched bit patterns during a write operation in the first embodiment;

FIG. 6 is a flowchart showing a write operation of a NAND flash memory according to a second embodiment; and

FIG. 7 is a view showing latched bit patterns during a write operation in the second embedment.

### DETAILED DESCRIPTION

In general, according to one embodiment, a nonvolatile semiconductor memory device includes a memory cells, a bit line, a sense amplifier, a memory circuit and an arithmetic circuit. The memory cells store multiple values in one memory cell. The bit line connected with the memory cells. The sense amplifier supplies a write voltage to the bit line. The memory circuit stores one of write data that is to be written in the memory cell and the number of writes. The arithmetic circuit changes the write data stored in the memory circuit to the number of writes and updates the number of writes. The arithmetic circuit controls the write voltage supplied from the sense amplifier based on the write data, and sets the number of writes in accordance with the write data stored in the memory circuit upon confirmation that each memory cell has reached a predetermined threshold voltage.

A nonvolatile semiconductor memory device according to an embodiment will now be described hereinafter with reference to the drawings. Here, a NAND flash memory will be taken as an example of a nonvolatile semiconductor memory device. Throughout the drawings, like reference numbers denote like parts for the explanation.

### First Embodiment

A NAND flash memory according to a first embodiment will be first described.

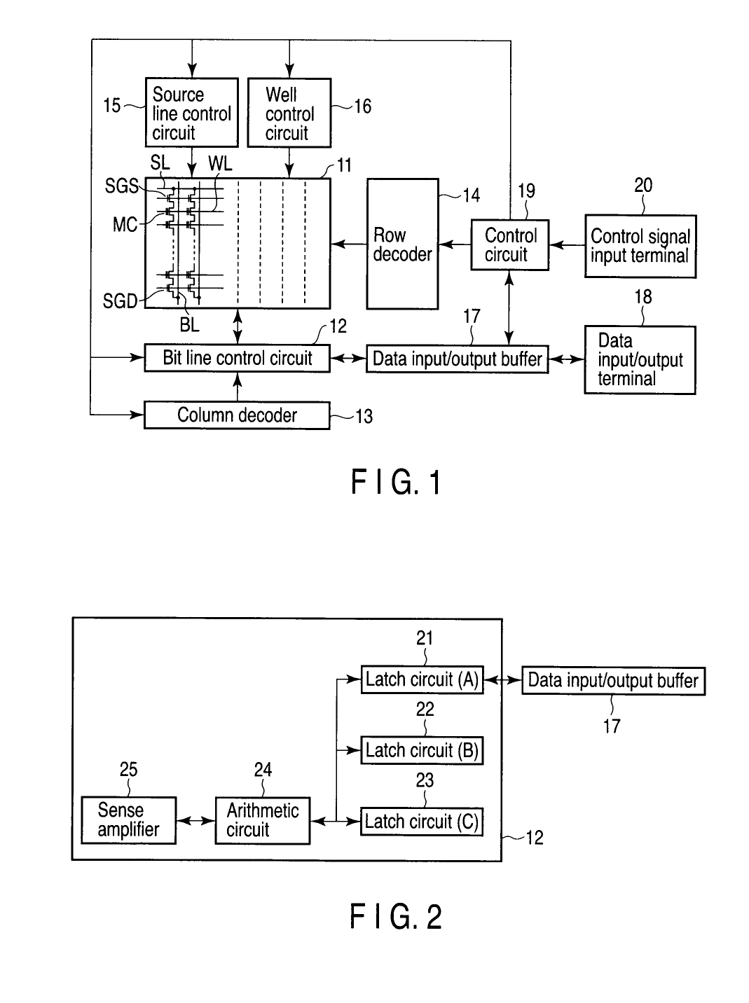

FIG. 1 is a block diagram showing a configuration of a NAND flash memory according to the first embodiment.

As depicted in the drawing, the NAND flash memory includes a memory cell array 11, a bit line control circuit 12, a column decoder 13, a row decoder 14, a source line control circuit 15, a well control circuit 16, a data input/output buffer 17, a data input/output terminal 18, a control circuit 19, and a control signal input terminal 20.

The memory cell array 11 has the following configuration. A structure in which a plurality of memory cells MC are connected in series is determined as a basic unit (NAND unit). One end of the NAND unit is connected with a bit line BL via a select gate SGD, and the other end of the NAND unit is connected with a source line SL via a select gate SGS.

Data reading and writing are collectively performed in units called one page that achieves connection with one word line WL. Moreover, a page aggregate sandwiched between the select gate SGD on the bit line side and the select gate SGS on the source line side constitutes a block.

The bit line control circuit 12 is arranged in accordance with each bit line BL, and it supplies a write voltage to a bit line at the time of a write operation and reads data stored in the memory cell MC from a bit line BL at the time of a read operation. During the read operation, data read to the bit line control circuit 12 from the memory cell MC is output to the data input/output terminal 18 via the data input/output buffer 17. The column decoder 13 selects a bit line BL connected with the memory cell MC in the memory cell array 11.

The row decoder 14 includes a word line driving circuit, and it selects and drives a word line WL connected with the memory cell in the memory cell array 11. The source line control circuit 15 and the well control circuit 16 supply predetermined write voltages to a source line and a well region at the time of a write operation, respectively.

Additionally, to the control circuit 19 are supplied external control signals such as a chip enable signal/CE, a write enable signal/WE, a read enable signal/RE, an address latch enable signal ALE, a command latch enable signal CLE and others from the control signal input terminal 20. The control circuit 19 controls operations of the bit line control circuit 12, the column decoder 13, the row decoder 14, the source line control circuit 15, the well control circuit 16 and the data input/output buffer 17 based on external control signals and commands supplied in accordance with operation modes, thereby effecting data write and erase sequence control and data read control.

A configuration of the bit line control circuit 12 arranged in accordance with each bit line will now be described.

FIG. 2 is a view showing a configuration of the bit line control circuit 12 in the NAND flash memory according to the first embodiment. Although each memory cell in the memory cell array 11 can store multilevel data, an example that each memory cell stores four values will be described below.

When the memory cell stores four values, the bit line control circuit 12 arranged in accordance with each bit line has three latches, i.e., latch A 21, a latch B 22 and latch C 23 as memory circuits, an arithmetic circuit 24 and a sense amplifier 25. The data input/output buffer 17 is connected with latch A 21, and latch A 21 is connected with latch B 22 and latch C 23. Latch A 21, latch B 22 and latch C 23 are connected with the arithmetic circuit 24, and the sense amplifier 25 is connected with the arithmetic circuit 24. Additionally, a bit line is connected with the sense amplifier 25.

The memory circuit stores either write data which is to be written into the memory cell or the number of writes. In accordance with write data stored in the memory circuit, the arithmetic circuit 24 transfers to the sense amplifier 25 the write data or non-write data if writing is terminated. The sense amplifier 25 supplies a write voltage to a bit line. Further, the arithmetic circuit 24 changes the write data stored in the memory circuit to the number of writes and updates the number of writes. Moreover, the arithmetic circuit 24 controls a write voltage supplied from the sense amplifier 25 based on the write data stored in the memory circuit and sets the number of writes in accordance with the write data stored in the memory circuit upon confirmation that the memory cell has reached a predetermined threshold voltage.

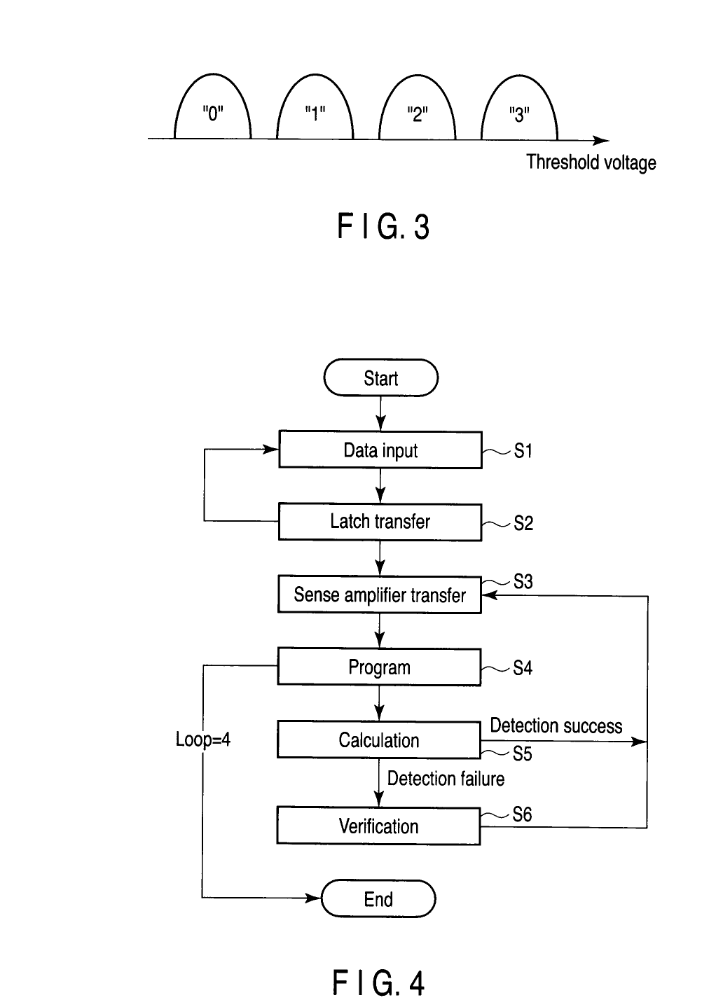

FIG. 3 shows a distribution of threshold voltages of four values in the memory cell. four-value data of “0”, “1”, “2” and “3” are shown in a threshold voltage ascending order.

A write operation in the NAND flash memory according to the first embodiment will now be described.

In the write operation, the write operation is usually terminated by first performing “rough writing” and then “actual writing”. In rough writing, writing is performed until a predetermined threshold voltage is reached, and then a predetermined number of writes are performed in accordance with write data to set a desired threshold voltage. The actual writing is effected after the rough writing, and a threshold voltage of each memory cell is accurately adjusted to fall within a threshold voltage distribution of each value.

In the embodiment, a description will now be given of rough writing as the write operation.

An outline of the write operation in the first embodiment will be first explained.

Writing is repeatedly performed with respect to a write target memory cell until a threshold voltage “1” is reached, and writing is terminated after reaching the threshold voltage “1” when writing “1”. Furthermore, when writing “2”, after the threshold voltage “1” is reached, X writes are performed, and then writing is terminated. When writing “3”, after the threshold voltage “1” is reached, Y writes are performed, and then writing is completed. At this time, write data which is to be stored in each latch and a bit pattern corresponding to the number of writes are optimized to reduce the number of data transfer operations in each latch. In this example, each of X and Y is a natural number less than or equal to 4 on the basis of the number of latches.

The write operation in the first embodiment will now be described in detail with reference to FIG. 4.

FIG. 4 is a flowchart showing a write operation in the first embodiment.

As shown in the drawing, write data is first input to latch A 21 from the data input/output buffer 17 (step S1). Subsequently, the write data is transferred to latch B 22 or latch C 23 from latch A 21 (step S2).

Then, when latch A 21, latch B 22 and latch C 23 are all high, the arithmetic circuit 24 determines that writing is terminated and transfers non-write data to the sense amplifier 25. On the other hand, if even one of latch A 21, latch B 22 and latch C 23 is low, the arithmetic circuit 24 transfers write data to the sense amplifier 25 (step S3).

Subsequently, writing (a program) is effected with respect to the memory cell MC. During this writing, data in each of latch A 21, latch B 22 and latch C 23 is confirmed (detection). If latch A 21 is low or latch A 21, latch B 22 and latch C 23 are all high (detection success), a circuit that counts the number of write loops starts to operate (step S4).

Then, if the detection fails in step S4, i.e., if latch A 21 is low or none of latch A 21, latch B 22 and latch C 23 is high, the control advances to step S6 to perform a confirmation (verification) operation of checking whether the write target memory cell MC has reached the threshold voltage “1”.

Here, if the write target memory cell has not reached the threshold voltage “1”, the control returns to step S3 to repeat the operations in steps S3, S4 and S6 until the threshold voltage “1” is reached.

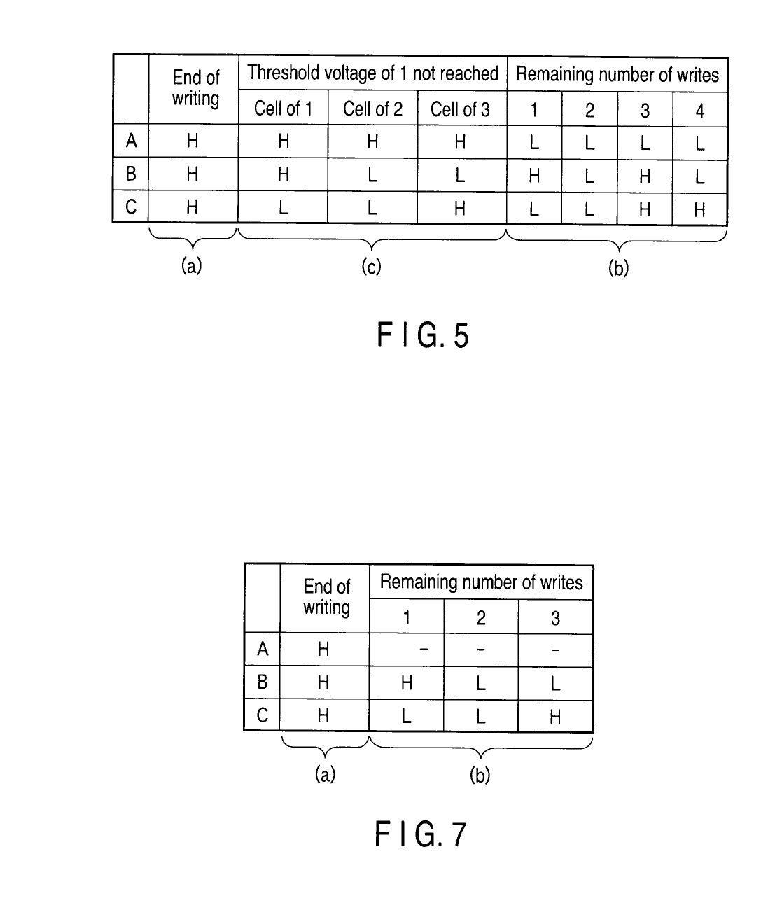

On the other hand, if the write target memory cell MC has reached the threshold voltage “1” in step S6, the bit pattern in latches A, B and C is changed to all-high as represented by (a) in FIG. 5 if the write target memory cell is a memory cell in which “1” is written, thereby terminating the writing.

Further, if the write target memory cell is a memory cell in which “2” is written, the bit pattern in each of latches A, B and C is changed to a bit pattern corresponding to X writes which correspond to two writes in this example. That is, bit pattern high-low-low in latches A, B and C indicated by (c) in FIG. 5 is changed to all-low indicated by (b) in FIG. 5.

Further, if the write target memory cell is a memory cell in which “3” is written, the bit pattern in each of latches A, B and C is changed to a bit pattern corresponding to Y writes which correspond to four writes in this example. That is, bit pattern high-low-high in latches A, B and C indicated by (c) in FIG. 5 is changed to low-low-high as indicated by (b) in FIG. 5.

Then, the control returns to step S3 to repeat the operations in step S3 and the subsequent steps. If verification succeeds in step S6, a calculation that subtracts one from each of the numbers of writes set in the latches, i.e., one to four in step S5 is performed. That is, an operation of changing the remaining number of writes N (N=1, 2, 3, 4) to a remaining number of writes N−1 is performed. Thereafter, the control returns to step S3 to repeat the operations in steps S3 to S5.

Further, when two writes are terminated with respect to the memory cell in which “2” is written and four writes are terminated with respect to the memory cell in which “3” is written, the bit pattern in latches A, B and C is changed to all-high to complete the writing. The above-described writing is executed with respect to all the write target memory cells, whereby writing is completed.

FIG. 5 shows bit patterns in the latches during the write operation, and it is a view showing the relationship between states of the memory cells during the write operation and the bit patterns in latches A, B and C.

Feature (a) of FIG. 5 is a bit pattern which is stored in the latch corresponding to a memory cell in which the writing has been terminated. Feature (b) is a bit pattern which is stored in the latch corresponding to a memory cell in which “2” or “3” is written if a threshold voltage “1” has been reached. Feature (c) is a bit pattern which is stored in the latch corresponding to a memory cell in which “1”, “2” or “3” is written when the threshold voltage “1” has not been reached.

When changing the bit pattern in the latch in step S6, the arithmetic circuit 24 provided between the sense amplifier 25 and the latches 21, 22 and 23 is utilized. High-low-low is stored in latches A, B and C corresponding to the memory cells in which “2” is written, respectively, as indicated by (c) in FIG. 5. To change the bit pattern to that corresponding to the two writes, changing high in latch A to low can suffice as indicated by (b) in FIG. 5.

Likewise, high-low-high is stored in latches A, B and C corresponding to memory cells in which “3” is written as indicated by (c) in FIG. 5. To change the bit pattern to that corresponding to the four writes, changing high in latch A to low as indicated by (b) in FIG. 5 can suffice.

As described above, in the first embodiment, when changing write data in the plurality of latches to a number of writes, since just changing the data in one latch can suffice, the data transfer operations for the latches can be reduced, and the time required for setting the number of writes can be decreased. As a result, the write time can be decreased.

It should noted that, in the rough writing depicted in FIG. 4, if the number of memory cells which has not exceeded the threshold voltage “1” and in which “1”, “2” or “3” is written is less than or equal to an allowable number (detection success) in the detection operation in step S4, the subsequent detection and verification operations do not have to be performed.

### Second Embodiment

In the second embodiment, if the write target memory cell is a memory cell in which “2” or “3” is written after reaching the threshold voltage “1” in step S6 in FIG. 4, the number of writes is set with respect to each of a plurality of corresponding latches, then one latch is opened, and the next write data is stored in the opened latch. At this time, a bit pattern indicative of the number of writes is optimized to reduce the number of data transfer operations. Any other structures are the same as those in the first embodiment.

In the second embodiment, one latch in three latches storing the numbers of writes can be opened, and the next write data can be stored in the opened latch. To open one of the latches, bit patterns corresponding to the numbers of writes must be created by using the remaining two latches. Therefore, the two latches can store four types of bit patterns alone, i.e., the end of writing and the remaining one, two and three writes.

After successfully confirming whether a write target memory cell has reached a threshold voltage “1”, a total of five bit patterns, i.e., the end of writing and the remaining one to four writes are required as bit patterns in the latches. However, when writing is performed once, the number of required bit patterns is a total of four, i.e., the end of writing and the remaining one to three writes, and hence the two latches can suffice. Therefore, one latch can be opened.

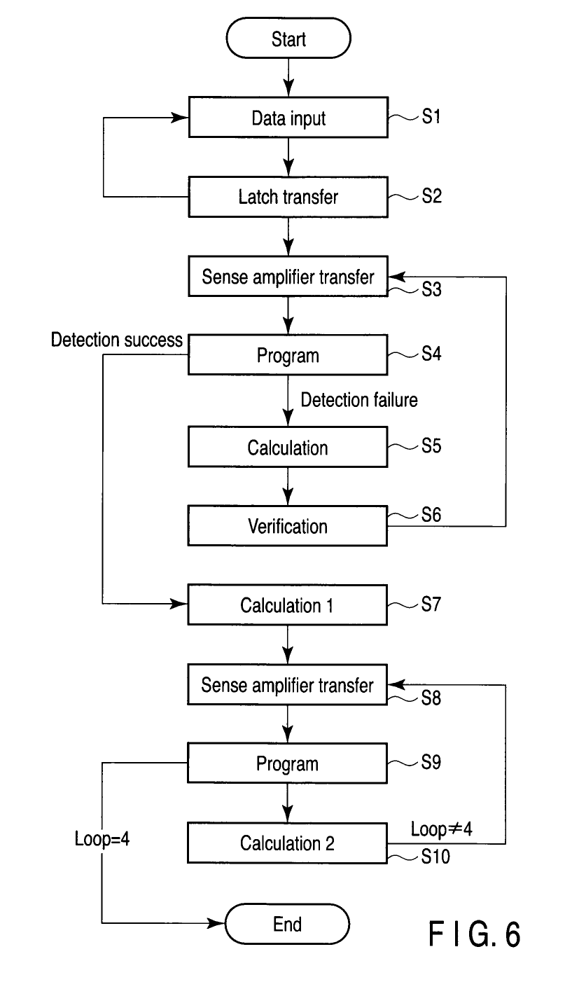

A write operation in the second embodiment will now be described with reference to FIG. 6.

FIG. 6 is a flowchart showing the write operation in the second embodiment.

As shown in the drawing, operations from the beginning to step S6 are equal to those in the first embodiment. When a write target memory cell has reached the threshold voltage “1”, the bit pattern in latches A, B and C is changed to all-high to terminate writing if the write target memory cell is a memory cell in which “1” is written.

Furthermore, when the write target memory cell is a memory cell in which “2” is written, the bit patterns in the latches are written X times, and they are changed to bit patterns corresponding to two writes. That is, the bit pattern in latches A, B and C is changed to all-low.

Moreover, when the write target memory cell is a memory cell in which “3” is written, the bit pattern in the latches are changed to bit patterns corresponding to Y writes which correspond to four writes in this example. That is, the bit pattern in latches A, B and C is changed to low-low-high.

Thereafter, the control returns to step S3 to effect the operation in step S3 and then advances to step S4 where writing (a program) is performed with respect to the memory cell. At this step S4, if verification has been successful in step S6, the data in latch A 21, latch B 22 and latch C 23 is not confirmed, and a circuit that counts the number of write loops starts to operate. Thereafter, control jumps to step S7.

In step S7, a calculation of subtracting one from the number of writes, i.e., each of one to three set with respect to latch A 21, latch B 22 and latch C 23 is executed. That is, the bit pattern indicated by (b) in FIG. 5 becomes the bit pattern indicated by (b) in FIG. 7. As a result, since data in latch A 21 is no longer required, and latch A 21 can be opened. Consequently, the next write data can be input to latch A 21.

Subsequently, if latch B 22 and latch C 23 are both high, an arithmetic circuit 24 determines that the writing is completed and transfers non-write data to a sense amplifier 25. On the other hand, if latch B 22 or latch C 23 is low, the arithmetic circuit 24 transfers the write data to the sense amplifier 25 (step S8).

Then, the control advances to step S9 where the writing (a program) is effected with respect to the memory cell. Subsequently, a calculation of subtracting one from each of the numbers of writes, i.e., one and two set with respect to latch B 22 and latch C 23 is performed.

Additionally, when the number of loops has reached four, writing is terminated. At this time, latch A has the next write data, latch B can be low or high, and latch C is high. Latch B is low only when the cell whose data indicative of the remaining number of writes is four is latched at a stage where verification has succeeded.

FIG. 7 shows bit patterns in latch B 22 and latch C 23 when latch A 21 is opened. Here, as shown in FIG. 7, the bit pattern low-high of latches B and C representing the remaining three writes is substituted by low-high of latches B and C representing the remaining four writes in FIG. 5. As a result, although the bit patterns must be usually changed from the remaining four writes to the remaining three writes, this operation is no longer necessary, whereby one data transfer operation can be reduced.

Further, as described above, since the writing is effected only when each of latches B and C is low, latch A is no longer necessary and can be opened. Furthermore, since the number of writes is used for recognizing the end of writing, the change of the bit patterns from the remaining three writes to the remaining two writes is no longer required, and the number of subsequent data transfer operations in the latches can be reduced to two in accordance with each loop.

As described above, in the embodiment, optimization of the data transfer operations, i.e., a reduction in the number of data transfer operations can be achieved based on setting bit patterns in the latches and changing the bit patterns, and optimizing an opening timing for each latch enables decreasing a write time.

Moreover, according to the embodiment, in the method of verification at a threshold voltage of one value in the rough writing of a four-value product of the NAND flash memory in which one memory cell can store four values and then setting the remaining number of writes associated with a write level with respect to a memory cell that has exceeded this threshold voltage, the relationship between the remaining number of writes and bit patterns in the latches is optimized to open a data cache (the latch), and unnecessary data transfer is reduced. Additionally, in a cache operation of storing the next write data in an opened data cache, a timing for opening the data cache is optimized, and an unnecessary detection or data transfer operation is omitted by changing determination of the end of writing after opening the data cache from the number of write loops from confirmation of the bit patterns. As a result, the write time in the NAND flash memory can be reduced.

In the embodiment, it is possible to provide the nonvolatile semiconductor memory device that can reduce the number of data transfer operations performed to set or change the write data or the number of writes stored in each latch and can decrease the write time by optimizing the opening timing of each latch.

It should be noted that the respective foregoing embodiments can be not only solely performed but can be appropriately combined to be performed.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device comprising:
a plurality of memory cells which store multiple values in one memory cell;
a bit line connected with the memory cells;
a sense amplifier which supplies a write voltage to the bit line;
a memory circuit which stores one of write data that is to be written in the memory cell and the number of writes; and
an arithmetic circuit which changes the write data stored in the memory circuit to the number of writes and updates the number of writes,
wherein the arithmetic circuit controls the write voltage supplied from the sense amplifier based on the write data, and sets the number of writes in accordance with the write data stored in the memory circuit upon confirmation that each memory cell has reached a predetermined threshold voltage.

2. The device according to claim 1,
wherein the arithmetic circuit sets the number of writes by changing data of one bit in the write data stored in the memory circuit.

3. The device according to claim 1,
wherein writing with respect to the memory cell is performed once after the arithmetic circuit sets the number of writes with respect to the memory circuit, and
the memory circuit includes a plurality of latches, and the arithmetic circuit opens one of the latches included in the memory circuit.

4. The device according to claim 3,
wherein the opened latch holds next write data.

5. The device according to claim 1,
wherein the memory cell stores any one of four values, and the memory circuit includes three latches.

6. The device according to claim 1,
wherein the memory cells are connected in series, and one end of the memory cells connected in series is connected with the bit line through a select gate.

7. A nonvolatile semiconductor memory device comprising:
a plurality of memory cells which store multiple values in one memory cell;
a bit line connected with the memory cells;
a column decoder which selects the bit line;
a sense amplifier which supplies a write voltage to the bit line and reads read data stored in the memory cell through the bit line;
a word line connected with the memory cell;
a row decoder which selects and drives the word line;
a memory circuit which stores one of write data that is to be written into the memory cell and the number of writes;
an arithmetic circuit which changes the write data stored in the memory circuit to the number of writes and updates the number of writes;
an input/output buffer which inputs the write data to the memory circuit and receives the read data from the memory circuit; and
a control circuit which controls the column decoder, the sense amplifier, the row decoder, the memory circuit, the arithmetic circuit and the input/output buffer,
wherein the arithmetic circuit controls the write voltage supplied from the sense amplifier based on the write data stored in the memory circuit, and
the control circuit sets the number of writes in accordance with the write data stored in the memory circuit upon confirmation that the memory cell has reached a predetermined threshold voltage.

8. The device according to claim 7,
wherein the arithmetic circuit sets the number of writes by changing data of one bit in the write data stored in the memory circuit.

9. The device according to claim 7,
wherein the control circuit performs writing once with respect to the memory cell after the arithmetic circuit sets the number of writes with respect to the memory circuit, and
the memory circuit includes a plurality of latches, and the arithmetic circuit opens one of the latches included in the memory circuit.

10. The device according to claim 9,
wherein the control circuit holds next write data in the opened latch.

11. The device according to claim 7,
wherein the control circuit performs writing with respect to the memory cell in accordance with the number of writes set in compliance with the write data.

12. The device according to claim 7,
wherein the memory cell stores any one of four values, and the memory circuit includes three latches.

13. The device according to claim 7,
wherein the memory cells are connected in series, and one end of the memory cells connected in series is connected with the bit line through a select gate.
